(19) United States
(12) Patent Application Publication
(10) Pub. No.: US 2016/0152486 A1
(43) Pub. Date: Jun. 2, 2016

(54) Preparation and Use of Zinc Compounds

(71) Applicant: HAYDALE GRAPHENE INDUSTRIES PLC, Ammanford, Carmarthenshire (GB)

(72) Inventor: Afshin Tarat, Ammanford, Carmarthenshire (GB)

(73) Assignee: Haydale Graphene Industries PLC, Hampshire (GB)

(21) Appl. No.: 14/905,771

(22) PCT Filed: Jul. 16, 2014
(86) PCT No.: PCT/GB2014/052170

§ 371 Date: Jan. 15, 2016

(30) Foreign Application Priority Data
Jul. 16, 2013 (GB) 1312698.2

(51) Int. Cl. C01G 9/02; H01L 21/02; C07F 3/06

(52) U.S. Cl. CPC C01G 9/02; C07F 3/06; H01L 21/02554; H01L 21/02628

(57) ABSTRACT

The present invention relates to methods of producing layered basic zinc acetate (LBZA) crystals from a reaction solution comprising zinc ions, acetate ions, and a basic compound, wherein (i) acetate is the only counter-ion for zinc in the reaction solution; and/or (ii) the basic compound is a hydroxyalkyl amine; and/or (iii) the basic compound is a first basic compound and the reaction solution further comprises a second basic compound having a higher pKa than the first basic compound. The invention also relates to methods of preparing ZnO materials from LBZA crystals, to methods of making electronic or semiconductor-based components from such ZnO materials, and to LBZA crystals and materials themselves.

This invention has to do with new methods of preparing layered basic zinc acetate (LBZA) materials, and to methods of preparing polycrystalline zinc oxide structures, particularly featuring nano-sized crystals, by heat treatment of the LBZA materials. The resulting materials are an aspect of the proposals. The resulting zinc oxide nanostructures are useful in a range of applications because of their characteristic properties.

### BACKGROUND

Zinc oxide (ZnO) is a semiconductor material known and used widely for its properties which may be exploited in microelectronics, optoelectronics, piezoelectric devices, gas sensors, photochemical and photovoltaic devices and the like. The effective and efficient preparation of ZnO nanostructures is accordingly of wide interest. They are known in several crystal morphologies including nanowires, nanorods, nanobelts and nanosheets.

Originally vapour-phase methods were used to make them—see e.g. “Zinc Oxide Nanostructures: Synthesis and Properties”, Fan and Lu, UC Irvine 2005. More recently wet chemical routes have been proposed, reducing processing temperatures and apparatus cost. Various publications have reported methods in which layered basic zinc acetate (LBZA) is formed as crystals from a zinc acetate solution, and subsequently heated (calcined or annealed) to form nanocrystalline ZnO by pyrolytic decomposition. See e.g. 12^{th} IEEE International Conference on Nanotechnology (Birmingham UK, August 2012) “Nanocrystalline ZnO obtained from pyrolitic decomposition of layered basic zinc acetate . . . ”, A. Tarat, R. Majithia et al, which summarises some earlier proposals and describes laboratory productions in which (i) solutions of zinc acetate with zinc nitrate and hexamethylenetetramine (HMTA), heating in a microwave oven to produce nanosheets of LBZA, filtering, and annealing to ZnO at from 400° C. to 600° C., or (ii) aqueous zinc acetate is simply heated at 65° C. for 20 hours to produce nanobelt LBZA. GB-A-2495074 is a related disclosure. See also J. Nanopart. Res. (2011) vol. 13 pp 5193-5202, “Evolution of the zinc compound nanostructures in zinc acetate single-source solution”, Wang et al, also showing the formation of LBZA nanobelts by cooling of simple aqueous zinc acetate.

While these earlier publications describe methods which are easy to perform compared with vapour phase methods, and have noted the potential availability of a variety of crystal morphologies as noted, there is substantial room for improvement as regards the morphological purity of the LBZA structures formed in solution, the yield, and in identifying acetate solutions which can form LBZA with adequate morphological purity, rapidly, conveniently and in substantial amounts.

### Our Proposals

Our proposals herein relate generally to processes in which LBZA crystals are formed from a solution of zinc and acetate ions, typically produced by dissolving zinc acetate dihydrate in deionised water. Preferably acetate is the only counter-ion for zinc in the solution, e.g. by zinc acetate being the only zinc compound used to form the solution. This is economical and simple and also gives better purity and yields than some known processes.

The concentration of zinc acetate affects both the ability to form crystals and the morphology and uniformity of the crystals, so to some extent it depends on the desired product morphology. There is not a strict limit but generally the zinc acetate concentration will be more than 0.01 M, and preferably at least 0.05 M. Usually it will be less than 0.3 M, or preferably not above 0.2 M. A typical preferable range is from 0.05 to 0.2 M, or from 0.07 to 0.12 M.

To promote formation of LBZA crystals, we include basic compound (one or more) in the reaction solution. This is known in itself, as previous proposals have used e.g. ammonia, urea or HMTA as mentioned above. In general we prefer mild base, and especially organic amine base, to promote uniformity of crystal size and habit in the product. Preferred bases have pKa at 25° C. not more than 9, preferably not more than 8.5. The pKa will generally be above 5, more preferably above 6. Organic amine bases can be used accordingly.

In our present work, we have found particularly good results with Tris base (tris(hydroxymethyl)methylamine), and the use of Tris base as the base (or as one among plural bases) in any method of the kind described herein is one new aspect of our proposals. However other organic bases can be used, such as HMTA mentioned above. Amines that may be used include substituted alkyl amines such as hydroxyalkylamines.

The quantity/concentration of the above-mentioned base having any of the above characteristics can be adjusted according to the conditions, because the rate and quality of crystal formation depend on the combined conditions including the concentrations of zinc and acetate, temperature and the like as well as on the strength of the base(s) used. Usually however base is used at more than 0.001 M and/or at not more than 0.5 M. Good results with particular bases mentioned herein are obtained at values from 0.01 M to 0.1 M, e.g. from 0.02 M to 0.04 M.

Another novel proposal here is to use more than one base. Preferably a base used (“first base”) satisfies the above “mild base” criteria), and is combined with a second base e.g. one having a higher pKa. Preferably the first base is used at a larger molar quantity than the second base, e.g. at least twice as much. A hydroxyalkyl amine, for example ethanolamine, is suitable as a second base. We have found in our experiments that addition of a second base such as ethanolamine in small quantities can improve the speed of the reaction and/or the quantity of product (yield against starting material) without affecting product quality, especially morphological purity. We find that, provided that the mild first base is added first to the zinc acetate solution, a stronger second base can be added without causing premature precipitation (which would happen if the stronger base were added initially).

The acetate/base combination constitutes a buffer. The pH of the reaction solution is important. Generally, crystals will not form at all below about 5.2, and above about pH 7.3 crystals are unlikely to be pure LBZA. Preferred pH is from 5.7 to 6.7, more preferably 6.1 to 6.3 or 6.4, most preferably about 6.2. Note: pH values stated herein are measured at room temperature, at 20° C.

### Nanosheets

In one aspect of our proposals, the process forms LBZA crystals in nanosheet form, and entails hydrothermal synthesis by microwave irradiation of the reaction solution to cause LBZA crystal formation. Under these conditions LBZA crystals form rapidly at small size, and by selecting the reaction solutions in line with our proposals herein, we find that LBZA in nanosheet form with high morphological purity and uniformity can be formed at good rates, in large volumes of reaction solution and at high yield relative to starting zinc acetate, representing an improvement over previous proposals.

As regards morphology: the LBZA crystals are small and delicate. Once they have formed there is little opportunity to select or classify the product according to the size or shape of the crystal bodies. For subsequent technical uses, it is highly desirable that the crystal bodies are all of the same general shape, all of the same general small size and in particular that the product is free of “rogue” crystals, especially those of the wrong shape, notably hexagonal prisms which constitute lumps among sheets or belts. Even a small percentage of these can devalue the entire product. Known processes such as described in the above IEEE article have achieved such uniformity or purity only with difficulty, and not at good yields or at acceptable rates and volumes. It is particularly in this respect that we find our new proposals about the reaction solutions advance the art. By simple trial and error, the amounts of the specified components can easily be adjusted to get LBZA nanosheets of good form, i.e. regular and rectangular in form, and with the layers within each sheet having generally smooth edges and fully overlapping. Control of the amount of base helps to regulate this.

The LBZA nanosheets are typically 10 to 50 nm thick. The length and width are each usually 200 nm or more, usually up to about 10 μm.

In this microwave process the time of microwave heating varies according to the microwave power and the volume being treated, but typically will be from 1 to 15 minutes and more usually from 2 to 10 minutes. Another advantage found with the present reaction solutions is that they can be less sensitive to variation in the irradiation time, compared with e.g. those disclosed in the above-mentioned August 2012 IEEE article (including zinc nitrate in the reaction solution): the latter could be reacted successfully only at small volumes and the morphological purity was lost if the treatment time varied from the determined optimum by more than a few seconds. By contrast, the present methods have been found to allow heating time variations of the order of minutes while maintaining product quality. This appears to be due to lower sensitivity to temperature variation near the container wall, which tends to form wrongly-shaped crystals.

### Nanobelts

Another aspect of our proposals forms LBZA in nanobelt form. In this aspect a reaction solution according to any of the general or preferred proposals above is allowed to stand and the nanobelt-form LBZA product forms gradually. It may stand at room temperature (e.g. 20-25° C.) or at moderately raised temperature, preferably not more than 75° C., more preferably less than 65° C., 50° C., 40° C. or 30° C. This proposal differs from previous published proposals in that the specified base is used, and also in that the process may be carried out at low to moderate temperature, or indeed at room temperature. Heating used in this method will be oven heating or some other form of externally-applied heating rather than in situ microwave irradiation of the reaction solution, because the formation of the crystals should be slow to preserve good morphological purity. Thus, the time for nanobelt crystal formation is typically from 1 to 20 hours, more usually from 2 to 15 hours or from 4 to 10 hours.

The skilled person will understand that some routine optimisation of these processes will be required in each case, depending on the specific concentrations used, the specific base(s) used, any heating/microwave conditions, temperature etc., to optimise the crystal form and size and the crystal morphological purity of the product. The formation of crystals is in itself routine; an advance herein is that we find that by using the present reaction solutions and processes, it is easier and quicker to obtain good yields of high morphological-purity LBZA product.

The LBZA crystals may be separated from the residual reaction solution by any conventional method, e.g. vacuum filtration, settling etc. They may be washed, e.g. with deionised water, before further processing.

For the pyrolytic decomposition (annealing/calcining) of the LBZA to form ZnO nanocrystals, known methods may be applied. During the process of decomposition to form ZnO, each LBZA body forms within its general shape an array of numerous small crystals of ZnO. Small nanocrystal size with concomitant high specific surface area is generally desirable for the end uses of these materials. Generally speaking the lower annealing temperatures form smaller crystals. In general the annealing temperature is likely to be between 100° C. and 1000° C., more preferably from 200 to 600° C. At temperatures above 600° C. there may be sintering of crystals, affecting some size-dependent properties such as surface area which are important for some purposes.

A further general aspect of the present invention is a method of making nanocrystalline ZnO microstructures, comprising forming LBZA by any method as proposed herein, followed by pyrolytic decomposition of the LBZA to form ZnO polycrystalline nanostructures.

These ZnO nanostructures/materials may then be used in any known or suitable application, such as in gas sensors.

A further general aspect of the present invention is a method comprising forming a polycrystalline ZnO material as described above and incorporating it, with or without intermediate processing steps, into an electronic or semiconductor-based component, such as a microelectronic component, optoelectronic component, sensor or photovoltaic generator.

ZnO nanostructures or materials obtained or obtainable by the present methods are also an aspect of the present proposals, being characterised by among other things their high level of morphological uniformity. Their use in electronic or semiconductor-based components, such as microelectronic components, optoelectronic components, sensors and photovoltaic generators, is an aspect herein as are the components themselves.

Examples of the present processes and materials are now described, with reference to the accompanying figures which are SEM photographs wherein:

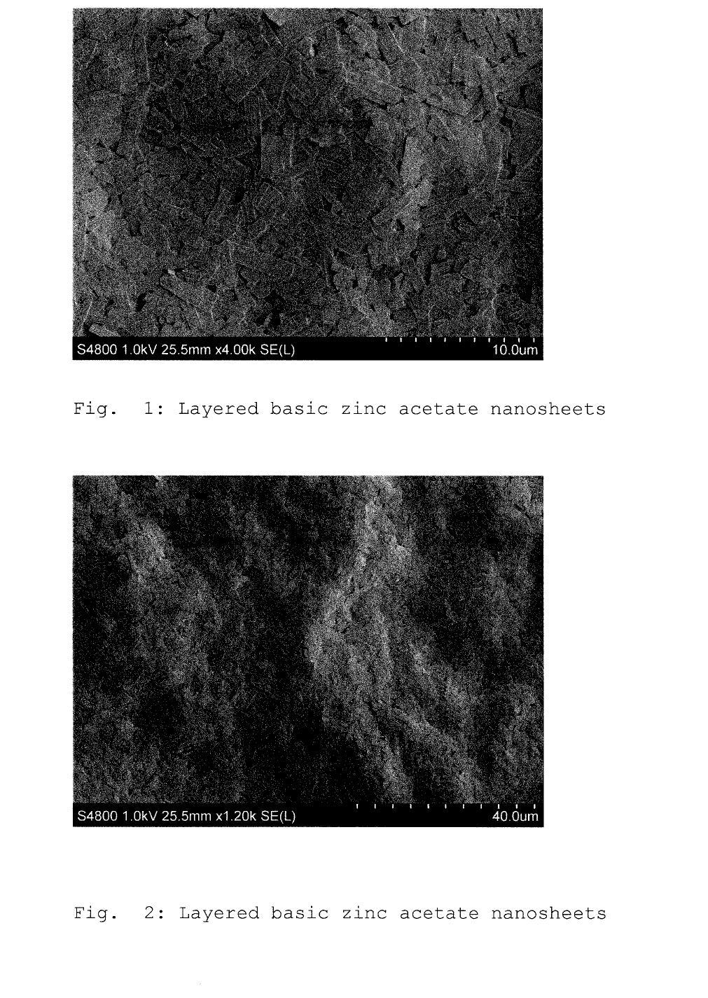

FIG. 1 and FIG. 2 show layered basic zinc acetate crystals in sheet form, made by a method embodying the invention, FIG. 2 being at lesser magnification;

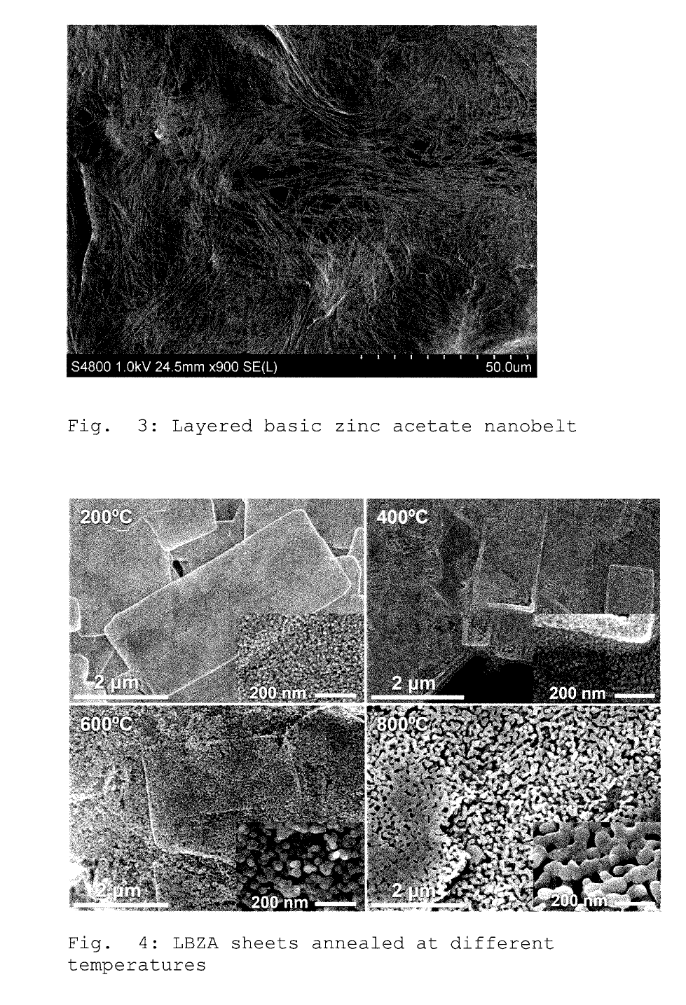

FIG. 3 shows layered basic zinc acetate crystals in belt form, made by a method embodying the invention;

FIGS. 4(a) to (d) show sheets of ZnO nanostructures, made by annealing the LBZA sheets of FIG. 1 at 200° C., 400° C., 600° C. and 800° C., the insets being at higher magnification;

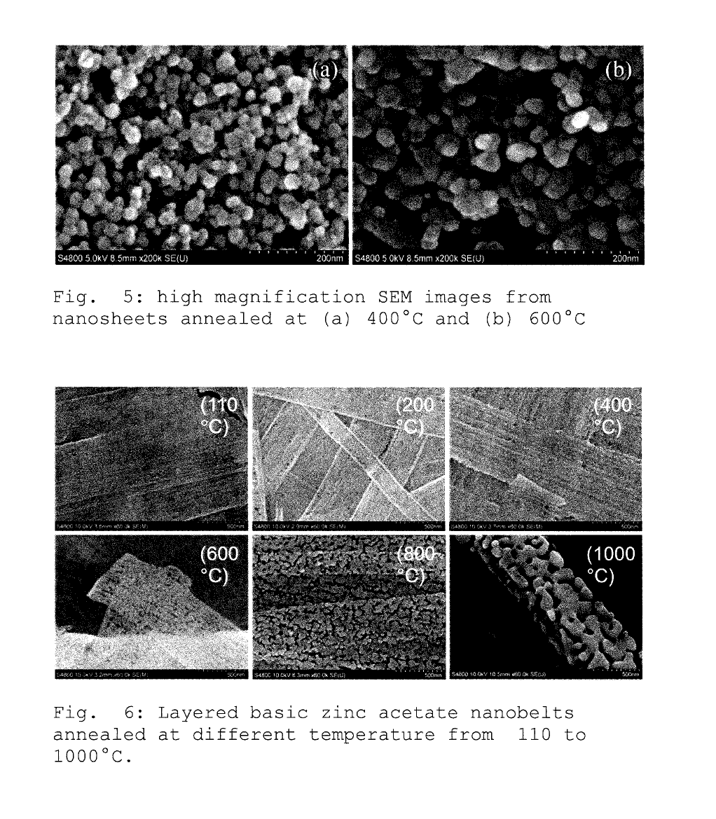

FIGS. 5(a) and (b) show the 400° C. and 600° C. annealed nanostructures at higher magnification of the crystallites, and

FIGS. 6(a) to (f) show belts of ZnO nanostructures made by annealing the LBZA belts of FIG. 3 at 110° C., 200° C., 400° C., 600° C., 800° C. and 1000° C.

### NANOSHEETS

### Experiment 1

In a first procedure, LBZA sheet-form crystals were prepared as follows.

(1) 13.17 g of zinc acetate dehydrate was dissolved in 600 ml of deionised water at room temperature (just under 20° C.) using a magnetic stirrer to obtain a clear homogeneous solution of 0.1M concentration. The pH is 5.2-5.3.

(2) 2.42 g of Tris base was added, continuing stirring, to obtain a homogeneous milky solution which is 0.033M Tris and has pH 6.2∓0.05 which is found to be an optimal pH for the process.

(3) The mixture, contained in an open glass vessel, was put into a standard commercial microwave oven which was then operated at 900 W for 5 minutes. The mixture, now containing visible shining crystals, was removed from the microwave—liquid temperature on removal from the oven was about 95° C.—and allowed to cool at room temperature.

(4) The mixture was filtered by vacuum filtration, recovering 0.7 g of LBZA crystals which were washed with deionised water and allowed to dry. The crystals are shown in the SEM photographs FIGS. 1 and 2. They are all of regular rectangular form. In this experiment almost all were smaller than 5 μm in maximum length. Importantly, the product exhibited 100% crystal purity, i.e. no hexagonal prism “lumps” were observable at all.

### Experiment 2

In a variant of the above process, Experiment 1 was repeated but 10 drops of ethanolamine (about 0.25 g) were added after the addition of the Tris base. The solution remained milky, but unlike Experiment 1 crystal formation began even before the mixture was heated in the microwave oven.

By the use of the ethanolamine, the results and product quality were the same as in Experiment 1, and the yield of crystals was increased to 0.9 g, varying between 0.9 and 1 g in repeats. However some variation in crystals was noted from run to run of the repeats, possibly associated with the exact manner of the initial addition of the ethanolamine.

### Experiment 3

The procedure of Experiment 1 was repeated, but increasing the duration of heating in the microwave oven first to 6, then to 7 and then 8 minutes. It was found that the yield and product quality were the same as in Experiment 1, i.e. the process was not very sensitive to the heating time.

### Comparative Experiment 1

The process described in the August 2012 IEEE publication referred to above was carried out using the solution described there i.e. 0.1M zinc acetate dihydrate, 0.02M zinc nitrate hexahydrate, and 0.02M HMTA as base. It was found that good quality rectangular LBZA crystals could be formed by heating for 2 minutes (120 s), and recovered by filtration as described. However the maximum reaction volume was 60 ml. Attempts to use larger volumes led to the formation of poorly-shaped crystals at the container wall, and process time criticality was severe: poor crystals formed if the heating time exceeded 120 s by 20 s. Also the yield was only 0.05 g, relatively less than in Experiments 1 to 3. The purity although good was not better than about 98% i.e. a few hexagonal crystals were visible in SEM images.

### Annealing (ZnO Nanostructures)

The sheet-form LBZA crystals from Experiment 1 were heated in air in a furnace at various temperatures. This converted the LBZA to crystallites of zinc oxide, still in the sheet form, as shown in FIGS. 4 and 5. This annealing is known in itself. FIGS. 4 and 5 show among other things the effect of annealing temperature. At temperatures of about 600° C. and above the ZnO nanocrystals tend to sinter, with some loss of available surface area.

### NANOBELTS

### Experiment 4

(1) Zinc acetate dihydrate was dissolved in 600 ml of deionized water in a glass container at room temperature to 0.1M and Tris base added to 0.033M as described in Experiment 1 above. The pH was 6.2 as before.

(2) The reaction mixture was then simply stood at room temperature for about eight hours. During this time, LBZA crystals in belt form (“nanobelts”) gradually formed.

(3) The belt-form LBZA crystals were recovered by vacuum filtration and washed. An SEM image is seen in FIG. 3. Again, the LBZA crystals were morphologically pure, i.e. 100% belt form without lumps of hexagonal crystal. Yield was 1.0-1.2 g.

It was known that LBZA belt crystals can be formed from aqueous zinc acetate, but it was not known that by including base, this could be done at room temperature.

The longer the solution stood, the longer the belt-form crystals grew.

### Experiment 5

Experiment 4 was repeated with the same reaction mixture, but the container was heated in a dry oven at 60° C. It was found that after two hours under these conditions, followed by cooling at room temperature, nanobelts formed to the same extent as after eight hours standing at room temperature. This demonstrated that a similar quality product can be obtained more quickly, at the expense of some energy for heating.

### Experiment 6

Experiment 4 was repeated, but adding ten drops of ethanolamine after the addition of the Tris base as in Experiment 2. It was found that the time needed to grow the same amount of crystals as in Experiment 4 was then much reduced, to about one hour (the yield of crystals was again about 1 to 1.2 g from 600 ml solution). In further experiments, it was found that the addition of larger quantities of ethanolamine could shorten the time for the formation of the belt-formed LBZA crystals even to less than a minute, although the length of the belt forms was reduced. Even so, high morphological purity was maintained.

This method of forming LBZA crystals is highly advantageous because heating is not necessary, and accordingly the volume to be prepared is not limited.

Annealing: ZnO Nanostructures from Belt-Formed Crystals

Recovered nanobelt LBZA crystals were annealed in air in a furnace at various temperatures, similarly as for the sheet-form crystals. The results for various annealing temperatures are shown in FIG. 6.

Accordingly, we have disclosed new and useful methods by which relatively large quantities of LBZA crystals can be formed in sheet or belt crystal format, using convenient processes which are not sensitive to variations in process conditions, and which produce crystalline product with exceptional crystal purity. The LBZA product is processable in turn to form nanocrystalline zinc oxide structures of corresponding morphological purity. The absence of lump-form crystals in the present products, a distinction from the prior art products, is a significant practical advantage when using the nanocrystalline zinc oxide in electronic products and the like.

1. A method of producing layered basic zinc acetate (LBZA) crystals from a reaction solution comprising zinc ions, acetate ions, and a basic compound, wherein:
acetate is the only counter-ion for zinc in the reaction solution; and/or
the basic compound is a hydroxyalkyl amine; and/or
the basic compound is a first basic compound, and the reaction solution further comprises a second basic compound having a higher pKa than the first basic compound.

2. A method according to claim 1, wherein zinc acetate is the only zinc compound used to form the reaction solution.

3. A method according to claim 1, wherein acetate is the only counter-ion for zinc in the reaction solution and the basic compound is a hydroxyalkyl amine.

4. A method according to claim 1, wherein the basic compound is tris(hydroxymethyl)methylamine.

5. A method according to claim 1, wherein the reaction solution is formed by dissolving zinc acetate in water.

6. A method according to claim 5, wherein the concentration of zinc acetate is between 0.01 to 0.3 M.

7. A method according to claim 1, wherein the basic compound has a pKa≦9 at 25° C.

8. A method according to claim 1, wherein the basic compound is a first basic compound, and the reaction solution further comprises a second basic compound having a higher pKa than the first basic compound, and wherein the second basic compound is added to the reaction solution after the first basic compound.

9. A method according to claim 1, wherein the basic compound is a first basic compound, and the reaction solution further comprises a second basic compound having a higher pKa than the first basic compound, wherein the second basic compound is a hydroxyalkyl amine.

10. A method according to claim 9, wherein the second basic compound is ethanolamine.

11. A method according to claim 1, wherein the reaction solution has a pH of 5.2 to 7.3.

12. A method according to claim 1, wherein the reaction solution has a pH of between 5.7 to 6.7.

13. A method according to claim 1, wherein the reaction solution has a pH of between 6.1 to 6.3.

14. A method according to claim 1, comprising subjecting the reaction solution to microwave irradiation.

15. A method according to claim 14, wherein the LBZA crystals are nanosheets.

16. A method according to claim 1, comprising allowing the reaction solution to stand.

17. A method according to claim 16, wherein the reaction solution is allowed to stand at ≦75° C.

18. A method according to claim 17, wherein the reaction solution is allowed to stand at ≦40° C.

19. A method according to claim 16, wherein the LBZA crystals are nanobelts.

20. A method of making a ZnO material, comprising producing LBZA crystals by a method according to claim 1, and then pyrolytically decomposing the LBZA crystals.

21. A method of making an electronic or semiconductor-based component, comprising making a ZnO material by a method according to claim 20, and incorporating the material into an electronic or semiconductor-based component.

22. A LBZA crystal obtainable by a method according to claim 1.

23. A ZnO material obtainable by a method according to claim 20.
